(19) United States
(12) Patent Application Publication
(10) Pub. No.: US 2026/0206343 A1
(43) Pub. Date: Jul. 16, 2026

(54) SENSOR PACKAGE STRUCTURE AND MANUFACTURING METHOD THEREOF

(71) Applicant: TONG HSING ELECTRONIC INDUSTRIES, LTD., Taoyuan City (TW)

(72) Inventors: JUI-HUNG HSU, Taoyuan City (TW); CHIEN-CHEN LEE, Taoyuan City (TW); Cheng-Chang Wu, Taoyuan City (TW)

(21) Appl. No.: 19/200,686

(22) Filed: May 7, 2025

(30) Foreign Application Priority Data
Jan. 15, 2025 (TW) 114101563

(51) Int. Cl. H10F 39/00

(52) U.S. Cl. CPC H10F 39/804; H10F 39/024; H10F 39/806; H10F 39/811

(57) ABSTRACT

A sensor package structure includes a ceramic substrate, a sensor chip mounted on and electrically coupled to the ceramic substrate, a ring-shaped supporting layer formed on the sensor chip, a light-permeable sheet disposed on the ring-shaped supporting layer, and an encapsulant that is formed on the ceramic substrate. The ceramic substrate, the sensor chip, the ring-shaped supporting layer, and the light-permeable sheet are embedded in the encapsulant. A bottom surface of the ceramic substrate and at least part of an outer surface of the light-permeable sheet are exposed from the encapsulant, and a bottom side of the encapsulant is flush with the bottom surface of the ceramic substrate.

### CROSS-REFERENCE TO RELATED PATENT APPLICATION

This application claims the benefit of priority to Taiwan Patent Application No. 114101563, filed on January 15, 2025. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is "prior art" to the disclosure described herein. All references cited and discussed in this specification are incorporated herein by reference in their entireties and to the same extent as if each reference was individually incorporated by reference.

### FIELD OF THE DISCLOSURE

The present disclosure relates to a package structure, and more particularly to a sensor package structure and a manufacturing method thereof.

### BACKGROUND OF THE DISCLOSURE

A conventional sensor package structure has a basic configuration that has become inflexible over time, such that an improvement on the basic architecture thereof has been neglected. For example, in the conventional sensor package structure, an encapsulant is formed on a substrate for protecting other components disposed on the substrate, but the substrate is not effectively protected by the encapsulant.

### SUMMARY OF THE DISCLOSURE

In response to the above-referenced technical inadequacies, the present disclosure provides a sensor package structure and a manufacturing method thereof for effectively improving on the issues associated with conventional sensor package structures.

In order to solve the above-mentioned problems, one of the technical aspects adopted by the present disclosure is to provide a manufacturing method of a sensor package structure, which includes a preparation step, a placing step, a first dispensing step, a second dispensing step, and a slicing step. The preparation step is implemented by providing a plurality of sensing modules. A manufacturing process of each of the sensing modules includes: mounting and electrically coupling a sensor chip to a ceramic substrate; forming a ring-shaped supporting layer on a top surface of the sensor chip; and fixing a light- permeable sheet onto the ring-shaped supporting layer so as to form one of the sensing modules. The placing step is implemented by placing the ceramic substrates of the sensing modules on a workbench. The first dispensing step is implemented by forming a blocking wall on the workbench. The blocking wall surrounds the sensing modules. The second dispensing step is implemented by forming an encapsulant layer inside of the blocking wall on the workbench. The sensing modules are embedded in the encapsulant layer, and an outer surface of the light-permeable sheet of each of the sensing modules is at least partially exposed from the encapsulant layer. The slicing step is implemented by cutting the encapsulant layer along a path that is defined along an outer side of the sensing modules and that is not in contact with the sensing modules, so as to divide the encapsulant layer into a plurality of encapsulants respectively covering the sensing modules therein. Each of the sensing modules and a corresponding one of the encapsulants are jointly defined as one of a plurality of sensor package structures.

In order to solve the above-mentioned problems, another one of the technical aspects adopted by the present disclosure is to provide a sensor package structure, which includes a ceramic substrate, a sensor chip, a ring- shaped supporting layer, a light-permeable sheet, and an encapsulant. The ceramic substrate has a first surface, a second surface being opposite to the first surface, and a surrounding lateral surface that is connected in-between the first surface and the second surface. The sensor chip is mounted on the first surface of the ceramic substrate and is electrically coupled to the ceramic substrate. A top surface of the sensor chip has a sensing region and a carrying region that surrounds the sensing region. The ring-shaped supporting layer is formed on the carrying region of the sensor chip. The light-permeable sheet is disposed on the ring-shaped supporting layer. The light-permeable sheet, the ring-shaped supporting layer, and the top surface of the sensor chip jointly define an enclosed space. The sensing region is located in the enclosed space. The encapsulant is formed on the first surface of the ceramic substrate and covers an entirety of the surrounding lateral surface, such that the ceramic substrate, the sensor chip, the ring-shaped supporting layer, and the light-permeable layer are embedded in the encapsulant. The second surface of the ceramic substrate and at least part of an outer surface of the light-permeable sheet are exposed from the encapsulant, and a bottom side of the encapsulant is flush with the second surface of the ceramic substrate.

In order to solve the above-mentioned problems, yet another one of the technical aspects adopted by the present disclosure is to provide a sensor package structure, which includes a ceramic substrate, a sensor chip, a ring- shaped supporting layer, a light-permeable sheet, and an encapsulant. The ceramic substrate has a first surface, a second surface being opposite to the first surface, and a surrounding lateral surface that is connected in-between the first surface and the second surface. The surrounding lateral surface of the ceramic substrate has a first riser surface connected to the first surface, a second riser surface connected to the second surface, and a tread surface that is connected in-between the first riser surface and the second riser surface. The sensor chip is mounted on the first surface of the ceramic substrate and is electrically coupled to the ceramic substrate. A top surface of the sensor chip has a sensing region and a carrying region that surrounds the sensing region. The ring-shaped supporting layer is formed on the carrying region of the sensor chip. The light- permeable sheet is disposed on the ring-shaped supporting layer. The light- permeable sheet, the ring-shaped supporting layer, and the top surface of the sensor chip jointly define an enclosed space. The sensing region is located in the enclosed space. The encapsulant is formed on the first surface of the ceramic substrate and covers the first riser surface and the tread surface, such that the sensor chip, the ring-shaped supporting layer, and the light-permeable layer are embedded in the encapsulant. The second surface of the ceramic substrate and at least part of an outer surface of the light-permeable sheet are exposed from the encapsulant.

Therefore, in the sensor package structure and the manufacturing method thereof provided by the present disclosure, the encapsulant is provided to cover other components therein (e.g., all components of the sensing module being embedded in the encapsulant), so that the sensor package structure can have a good protective effect through the encapsulant (e.g., the surrounding lateral surface of the ceramic substrate being entirely protected by the encapsulant).

Moreover, a carrier of the sensor package structure provided by the present disclosure is chosen by the ceramic substrate having a small coefficient of thermal expansion (CTE), so that the ceramic substrate is not easily affected by the thermal expansion of the encapsulant to generate a warpage, thereby enabling the ceramic substrate to be embedded in the encapsulant. In other words, any package structure that does not have a ceramic substrate embedded in an encapsulant thereof is different from the sensor package structure of the present disclosure.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic perspective view of a sensor package structure according to a first embodiment of the present disclosure;

FIG. 2 is a schematic top view of FIG. 1;

FIG. 3 is a schematic cross-sectional view taken along line III-III of FIG. 1;

FIG. 4 is a schematic top view showing a manufacturing method of the sensor package structure after a first dispensing step is implemented according to the first embodiment of the present disclosure;

FIG. 5 is a schematic cross-sectional view taken along line V-V of FIG. 4;

FIG. 6 is a schematic cross-sectional view showing a configuration of FIG. 5 after a second dispensing step is implemented;

FIG. 7 is a schematic top view showing the manufacturing method after the first dispensing step is implemented according to a second embodiment of the present disclosure;

FIG. 8 is a schematic cross-sectional view taken along line VIII-VIII of FIG. 7;

FIG. 9 is a schematic cross-sectional view showing a configuration of FIG. 8 after the second dispensing step is implemented;

FIG. 10 is a schematic cross-sectional view of the sensor package structure according to a third embodiment of the present disclosure; and

FIG. 11 is a schematic cross-sectional view of the sensor package structure in another configuration according to the third embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of "a," "an" and "the" includes plural reference, and the meaning of "in" includes "in" and "on." Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as "first," "second" or "third" can be used to describe various components, signals or the like, which are for distinguishing one component/signal from another one only, and are not intended to, nor should be construed to impose any substantive limitations on the components, signals or the like.

### First Embodiment

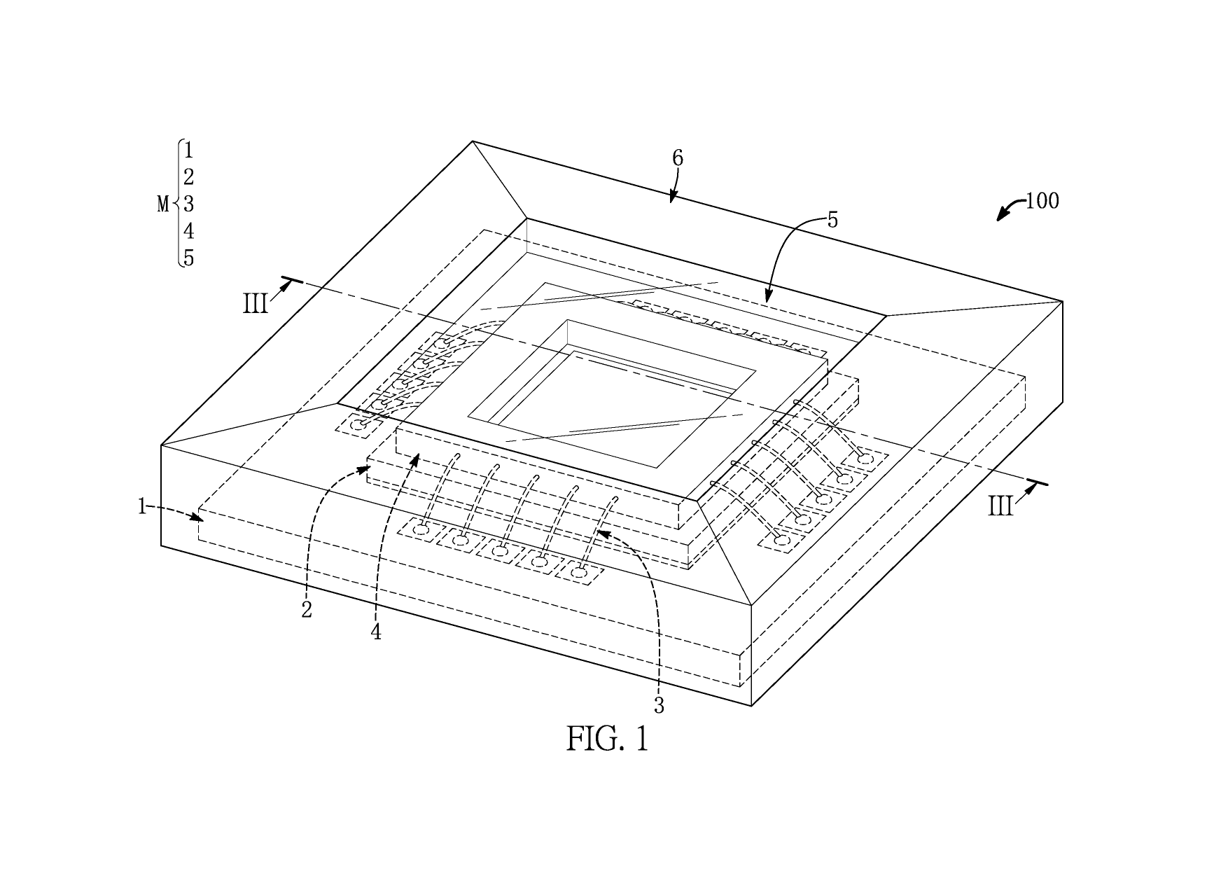

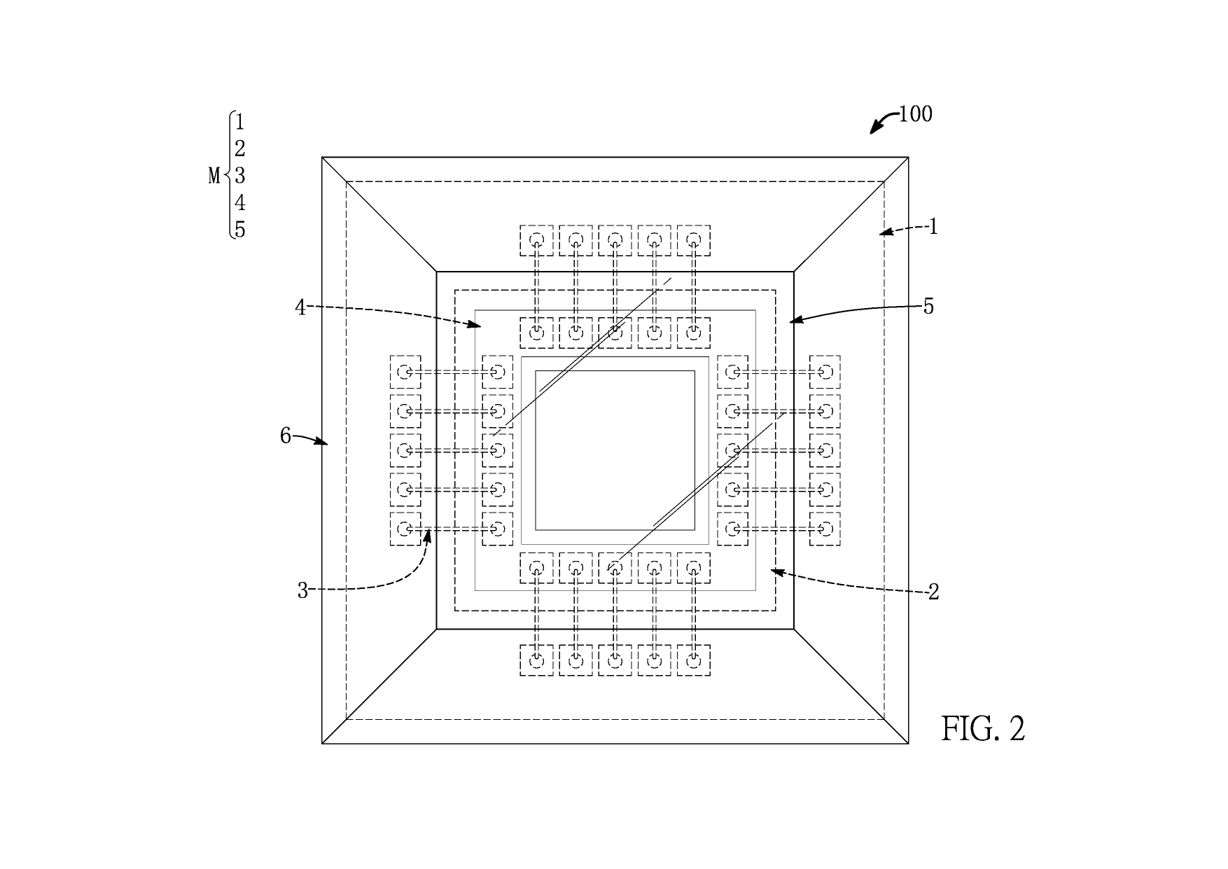

Referring to FIG. 1 to FIG. 6, a first embodiment of the present disclosure is provided. The present embodiment provides a sensor package structure 100 and a manufacturing method thereof, and the sensor package structure 100 can be manufactured by implementing the manufacturing method described in the present embodiment, but the present disclosure is not limited thereto. For example, in other embodiments of the present disclosure not shown in the drawings, the sensor package structure 100 can be manufactured by implementing a method other than the manufacturing method of the present embodiment. In addition, in order to clearly understand the present embodiment, the following description first describes the manufacturing method, and then describes the sensor package structure 100.

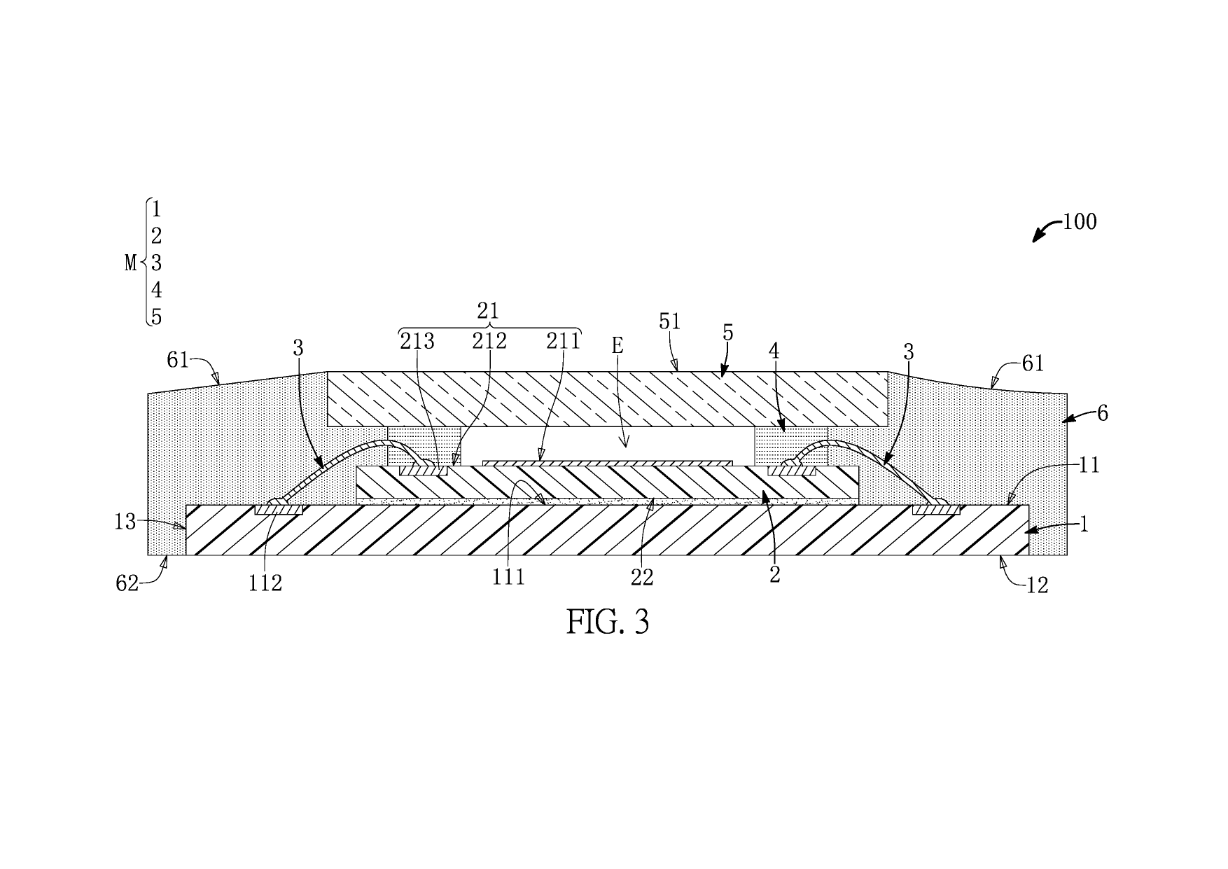

As shown in FIG. 3 to FIG. 6, the manufacturing method in the present embodiment includes a preparation step S110, a placing step S120, a first dispensing step S130, a second dispensing step S140, and a slicing step S150. It should be noted that the manufacturing method is provided to manufacture the sensor package structure 100 by implementing the above steps S110 - S150, so that the manufacturing method of the present embodiment can refer to a corresponding description of the sensor package structure 100. The following description substantially describes each of the steps S110 - S150 of the manufacturing method, but the present disclosure is not limited thereto.

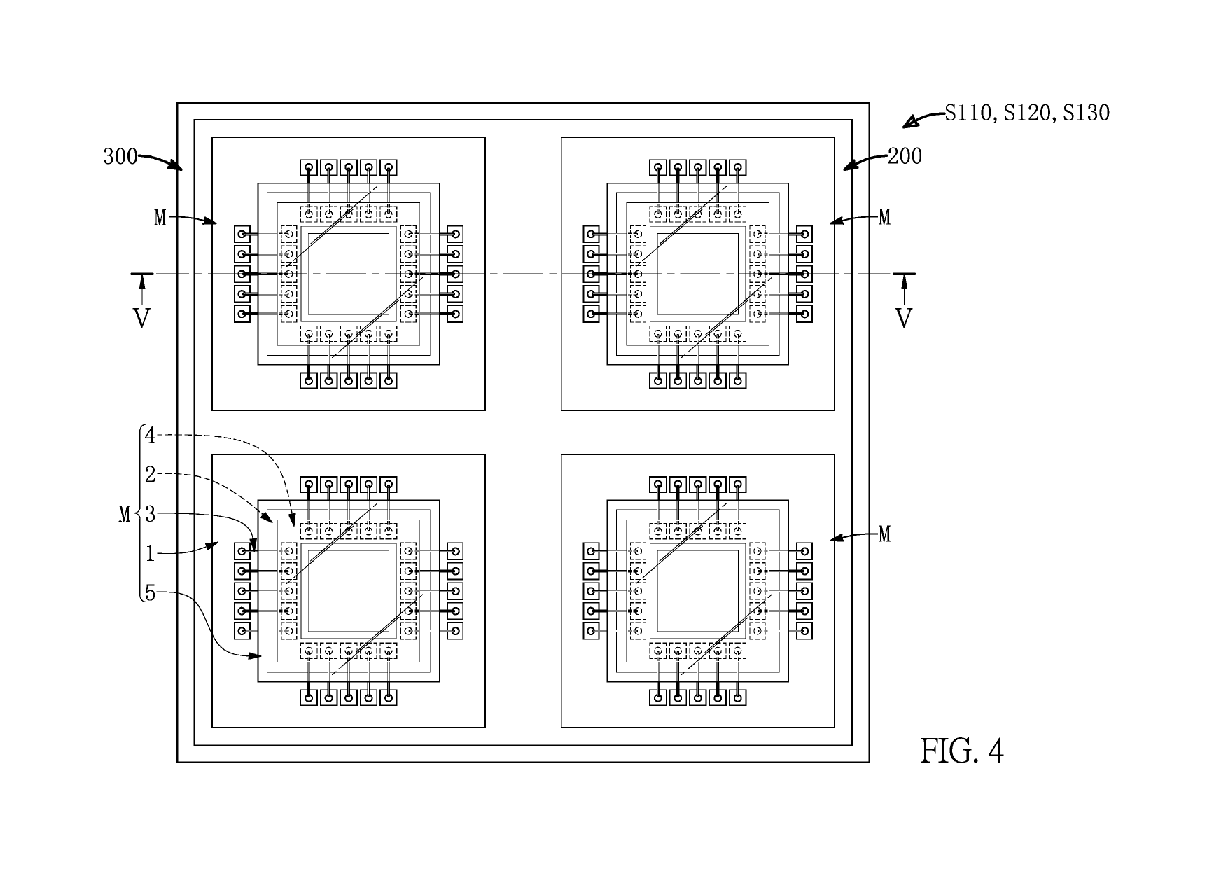

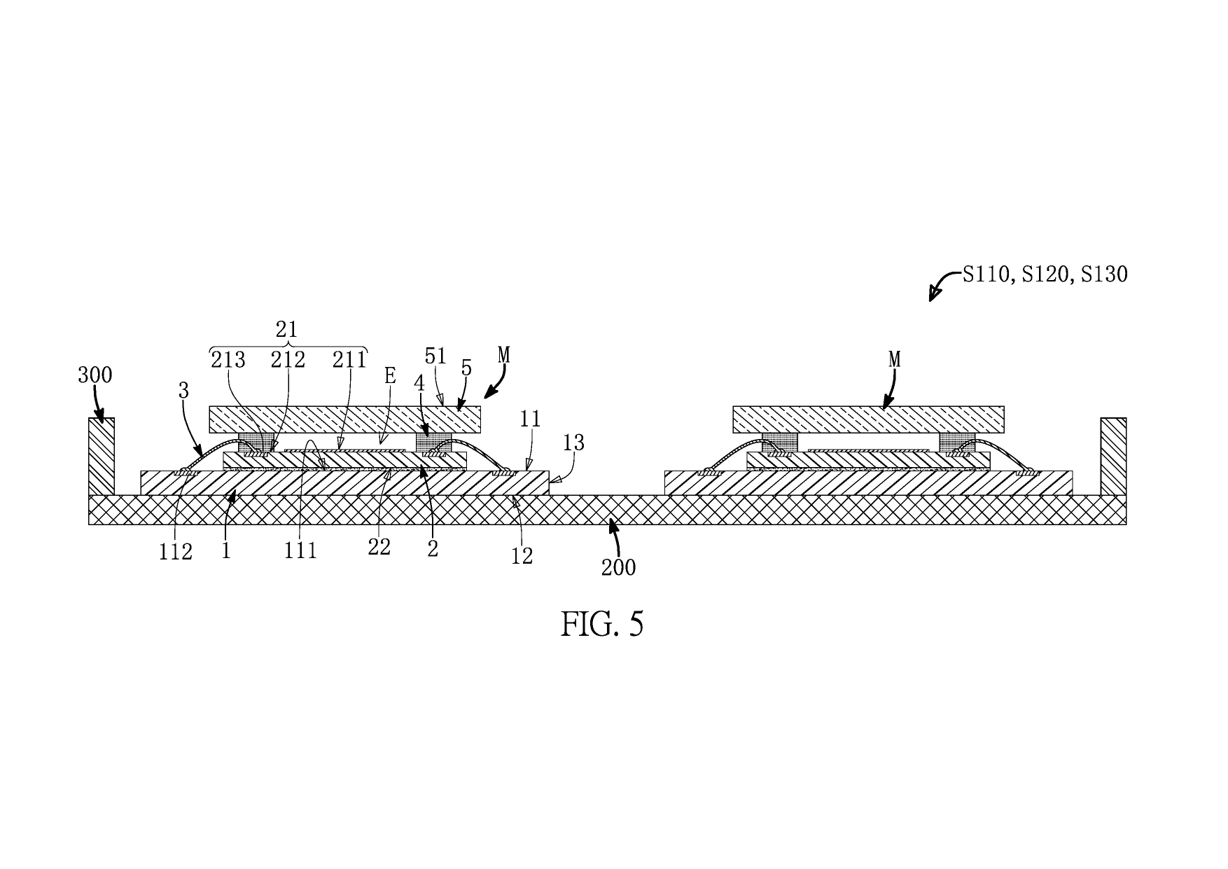

As shown in FIG. 4 and FIG. 5, the preparation step S110 is implemented by providing a plurality of sensing modules M that are independent from each other. A manufacturing process of each of the sensing modules M includes: mounting and electrically coupling a sensor chip 2 to a ceramic substrate 1; forming a ring-shaped supporting layer 4 on a top surface 21 of the sensor chip 2; and fixing a light-permeable sheet 5 onto the ring- shaped supporting layer 4 so as to form one of the sensing modules M.

Specifically, the manufacturing process of each of the sensing modules M in the present embodiment further includes: using a plurality of metal wires 3 to connect the ceramic substrate 1 and the sensor chip 2 after the sensor chip 2 is mounted on the ceramic substrate 1, such that the ceramic substrate 1 and the sensor chip 2 are electrically coupled to each other through the metal wires 3, but the present disclosure is not limited thereto. For example, in other embodiments of the present disclosure not shown in the drawings, the sensor chip 2 can be mounted on and electrically coupled to the ceramic substrate 1 in a flip-chip manner according to practical requirements.

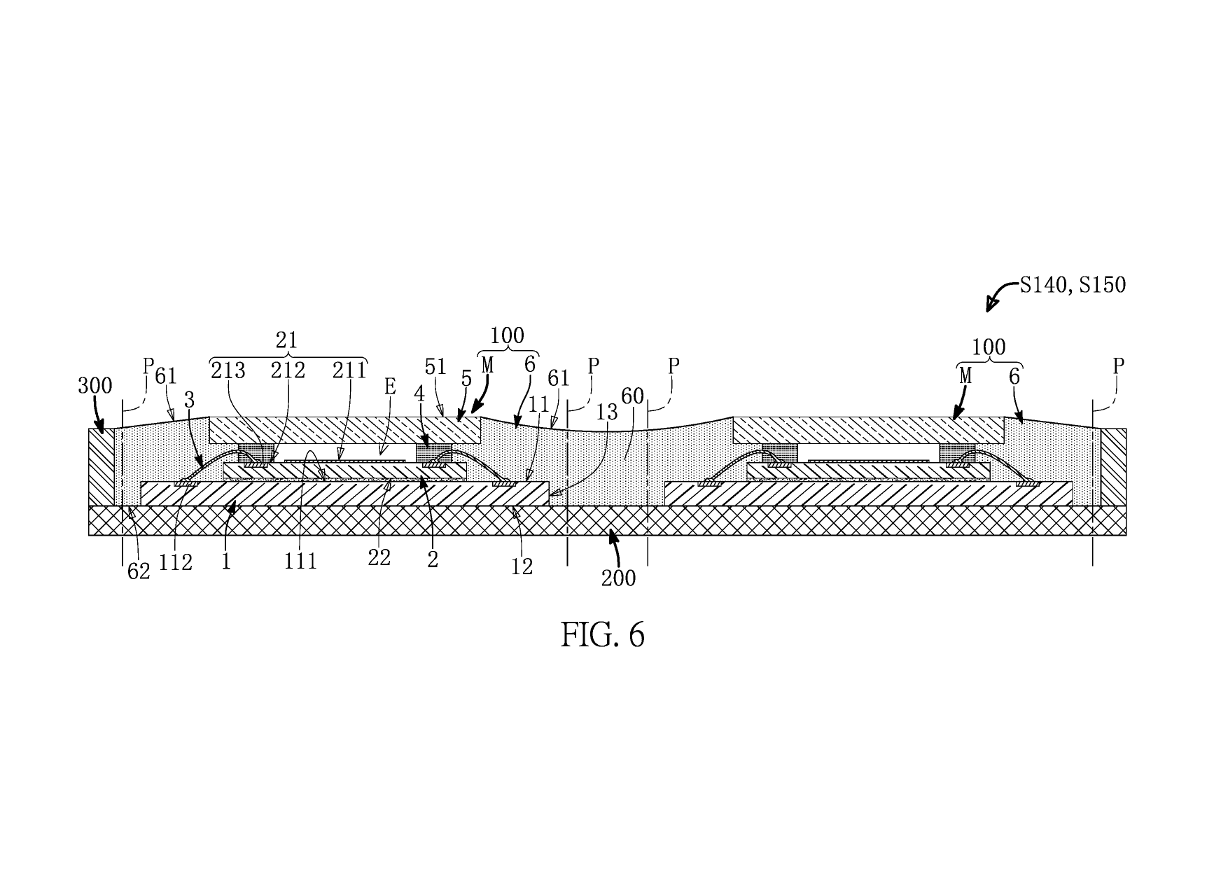

As shown in FIG. 4 and FIG. 5, the placing step S120 is implemented by placing the ceramic substrates 1 of the sensing modules M on a workbench 200. In the present embodiment, the sensing modules M are spaced apart from each other and are preferably in a matrix arrangement, thereby facilitating a following implementation of the slicing step S150 (as shown in FIG. 6).

As shown in FIG. 4 and FIG. 5, the first dispensing step S130 is implemented by forming a blocking wall 300 on the workbench 200. The blocking wall 300 is ring-shaped and surrounds the sensing modules M. In the present embodiment, a distance between the blocking wall 300 and one of the sensing modules M adjacent thereto is preferably less than or equal to a distance between any two of the sensing modules M adjacent to each other, and a top side of the blocking wall 300 is preferably not higher than an outer surface 51 of the light-permeable sheet 5 of each of the sensing modules M with respect to the workbench 200, but the present disclosure is not limited thereto.

As shown in FIG. 6, the second dispensing step S140 is implemented by forming an encapsulant layer 60 inside of the blocking wall 300 on the workbench 200. The sensing modules M are embedded in the encapsulant layer 60, and the outer surface 51 of the light-permeable sheet 5 of each of the sensing modules M is at least partially exposed from the encapsulant layer 60.

Specifically, before the second dispensing step S140 is implemented, since the top side of the blocking wall 300 is not higher than the outer surface 51 of the light-permeable sheet 5 of each of the sensing modules M, the encapsulant layer 60 in the implementation of the second dispensing step S140 can be effectively controlled to avoid extending to the outer surface 51 of any one of the light-permeable sheets 5.

As shown in FIG. 6, the slicing step S150 is implemented by cutting the encapsulant layer 60 along a path P that is defined along an outer side of the sensing modules M and that is not in contact with the sensing modules M, so as to divide the encapsulant layer 60 into a plurality of encapsulants 6 respectively covering (or encapsulating) the sensing modules M therein. Each of the sensing modules M and a corresponding one of the encapsulants 6 are jointly defined as one of a plurality of sensor package structures 100 (as shown in FIG. 3).

It should be noted that in any one of the sensor package structures 100 provided by the present embodiment, two top side regions 61 of the encapsulant 6 respectively arranged at two opposite sides of the light-permeable sheet 5 are in a non-symmetrical arrangement with respect to the light-permeable sheet 5 (e.g., angles of the two top side regions 61 with respect to the outer surface 51 of the light-permeable sheet 5 being provided with a slight difference therebetween), but the present disclosure is not limited thereto.

Accordingly, the implementation of the manufacturing method is described in the above description, and the following description describes the sensor package structure 100 manufactured by implementing the manufacturing method, such that technical features of the sensor package structure 100 can refer to the above description of the manufacturing method, but the present disclosure is not limited thereto. For example, in other embodiments of the present disclosure not shown in the drawings, the sensor package structure 100 can be manufactured by implementing other methods according to practical requirements.

As shown in FIG. 1 to FIG. 3, the sensor package structure 100 in the present embodiment includes a ceramic substrate 1, a sensor chip 2 mounted on the ceramic substrate 1, a plurality of metal wires 3 electrically coupled to the ceramic substrate 1 and the sensor chip 2, a ring-shaped supporting layer 4 formed on the sensor chip 2, a light-permeable sheet 5 disposed on the ring- shaped supporting layer 4, and an encapsulant 6 that is formed on the ceramic substrate 1, but the present disclosure is not limited thereto.

It should be noted that the sensor package structure 100 in the present embodiment includes the above components, but can be adjusted or changed according to design requirements. For example, in other embodiments of the present disclosure not shown in the drawings, the sensor package structure 100 can be provided without the metal wires 3, and the sensor chip 2 is fixed onto and electrically coupled to the ceramic substrate 1 in a flip-chip manner. The structure and connection relationship of each component of the sensor package structure 100 are described in the following description.

The ceramic substrate 1 of the present embodiment has a square shape or a rectangular shape, but the present disclosure is not limited thereto. The ceramic substrate 1 has a first surface 11, a second surface 12 being opposite to the first surface 11, and a surrounding lateral surface 13 that is connected in- between the first surface 11 and the second surface 12.

Specifically, the first surface 11 of the ceramic substrate 1 includes a chip-bonding region 111 arranged approximately on a center portion thereof, and the ceramic substrate 1 includes a plurality of bonding pads 112 that are disposed on the first surface 11 and that are arranged outside of the chip- bonding region 111. The bonding pads 112 in the present embodiment are in a ring-shaped arrangement, but the present disclosure is not limited thereto. For example, in other embodiments of the present disclosure not shown in the drawings, the bonding pads 112 can be arranged in two rows respectively at two opposite sides of the chip-bonding region 111.

The sensor chip 2 in the present embodiment has a square shape or a rectangular shape, and is an image sensor chip, but the present disclosure is not limited thereto. A bottom surface 22 of the sensor chip 2 is fixed onto the chip- bonding region 111 of the ceramic substrate 1 through a chip-bonding adhesive. In other words, the sensor chip 2 is arranged to be surrounded on the inside of the bonding pads 112. Moreover, a top surface 21 of the sensor chip 2 has a sensing region 211 and a carrying region 212 that has a ring shape arranged around the sensing region 211. Two ends of each of the metal wires 3 are respectively connected to the ceramic substrate 1 and the carrying region 212 of the sensor chip 2, so that the ceramic substrate 1 and the sensor chip 2 are electrically coupled to each other.

Specifically, the sensor chip 2 includes a plurality of connection pads 213 arranged on the carrying region 212. In other words, the connection pads 213 are arranged outside of the sensing region 211. The number and positions of the connection pads 213 of the sensor chip 2 in the present embodiment correspond to those of the bonding pads 112 of the ceramic substrate 1. In other words, the connection pads 213 in the present embodiment are substantially in a ring-shaped arrangement.

Moreover, one end of the metal wires 3 is connected to the bonding pads 112, and another end of the metal wires 3 is connected to the connection pads 213. In other words, the two ends of each of the metal wires 3 are respectively connected to one of the bonding pads 112 and the corresponding connection pad 213. Any one of the metal wires 3 can be configured in a normal wire-bonding manner or a reverse wire-bonding manner according to design requirements, and the present disclosure is not limited thereto.

The ring-shaped supporting layer 4 is disposed on the carrying region 212 of the sensor chip 2 and surrounds the sensing region 211. In the present embodiment, each of the connection pads 213 and a part of a corresponding one of the metal wires 3 connected thereto are embedded in the ring-shaped supporting layer 4, and a remaining part of each of the metal wires 3 is embedded in the encapsulant 6, but the present disclosure is not limited thereto. For example, in other embodiments of the present disclosure not shown in the drawings, the ring-shaped supporting layer 4 can be arranged inside of the metal wires 3 and is not in contact with any one of the metal wires 3 (i.e., each of the metal wires 3 being arranged outside of the ring-shaped supporting layer 4 and being entirely embedded in the encapsulant 6).

The light-permeable sheet 5 in the present embodiment is a transparent and flat glass board, but the present disclosure is not limited thereto. The light- permeable sheet 5 is disposed on the ring-shaped supporting layer 4, and the light-permeable sheet 5, the ring-shaped supporting layer 4, and the top surface 21 of the sensor chip 2 jointly define an enclosed space E. It should be noted that the enclosed space E in the present embodiment is preferably not filled within any adhesive, but the present disclosure is not limited thereto.

The encapsulant 6 is formed on the first surface 11 of the ceramic substrate 1 and covers an entirety of the surrounding lateral surface 13 of the substrate 1, such that the ceramic substrate 1, the sensor chip 2, the ring-shaped supporting layer 4, the light-permeable layer 5, and at least part of each of the metal wires 3 are embedded in the encapsulant 6. The second surface 12 of the ceramic substrate 1 and at least part of the outer surface 51 of the light- permeable sheet 5 are exposed from the encapsulant 6, and a bottom side 62 of the encapsulant 6 is flush with (or coplanar with) the second surface 12 of the ceramic substrate 1.

It should be noted that the encapsulant 6 in the present embodiment is a solidified liquid compound, but the present disclosure is not limited thereto. For example, in other embodiments of the present disclosure not shown in the drawings, the encapsulant 6 can be a molding compound.

In summary, in the sensor package structure 100 and the manufacturing method thereof provided by the present embodiment, the encapsulant 6 is provided to cover other components therein (e.g., all components of the sensing module M being embedded in the encapsulant 6), so that the sensor package structure 100 can have a good protective effect through the encapsulant 6 (e.g., the surrounding lateral surface 13 of the ceramic substrate 1 being entirely protected by the encapsulant 6).

Moreover, a carrier of the sensor package structure 100 is chosen by the ceramic substrate 1 having a small coefficient of thermal expansion (CTE), so that the ceramic substrate 1 is not easily affected by the thermal expansion of the encapsulant 6 to generate a warpage, thereby enabling the ceramic substrate 1 to be embedded in the encapsulant 6. In other words, any package structure that does not have a ceramic substrate embedded in an encapsulant thereof is different from the sensor package structure 100 of the present embodiment.

### Second Embodiment

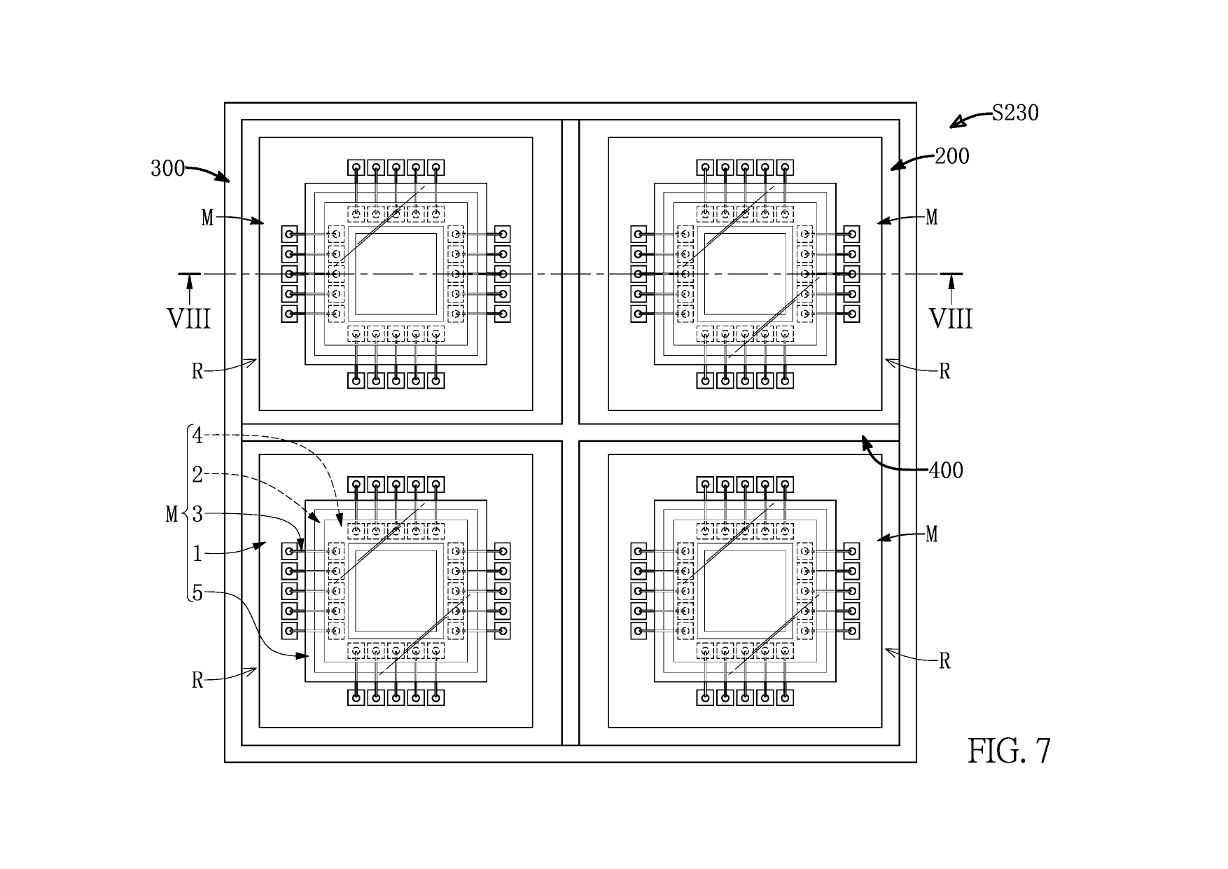

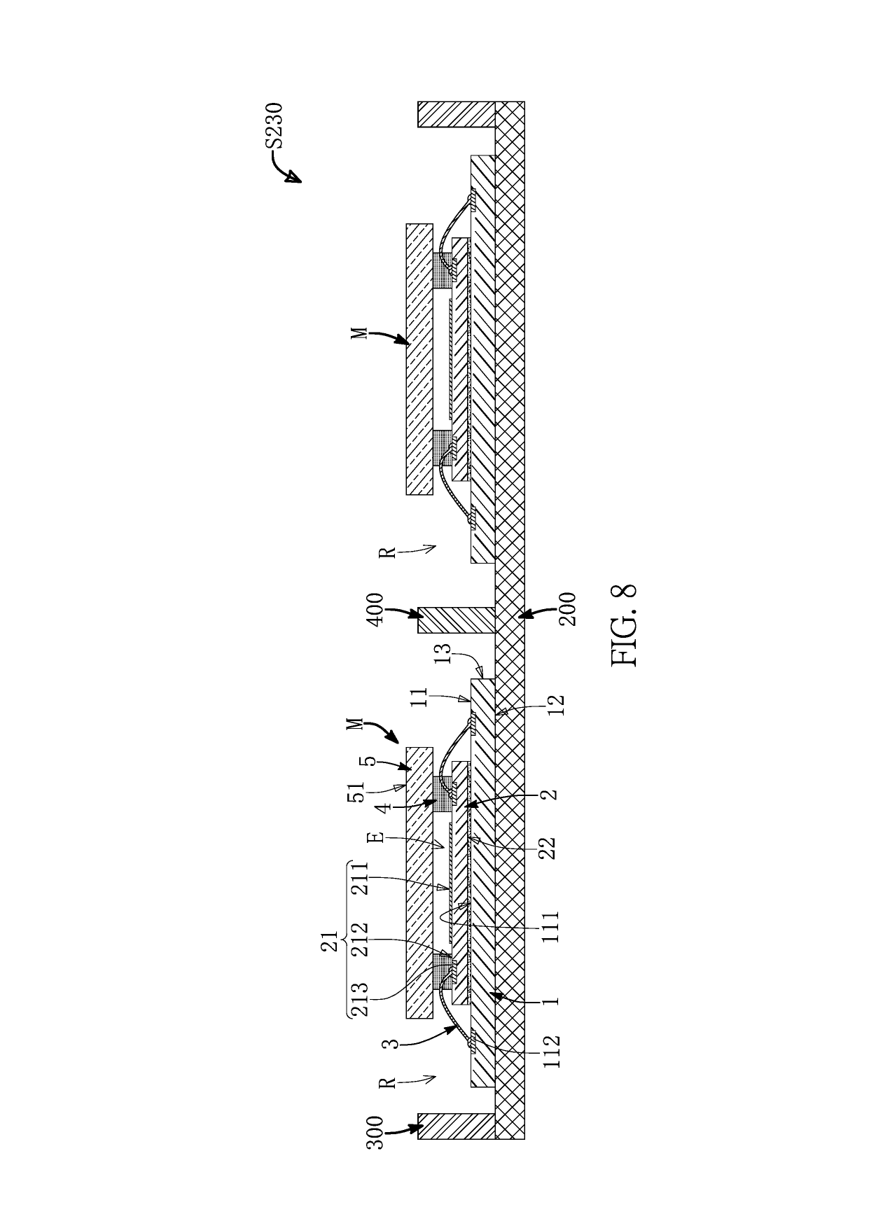

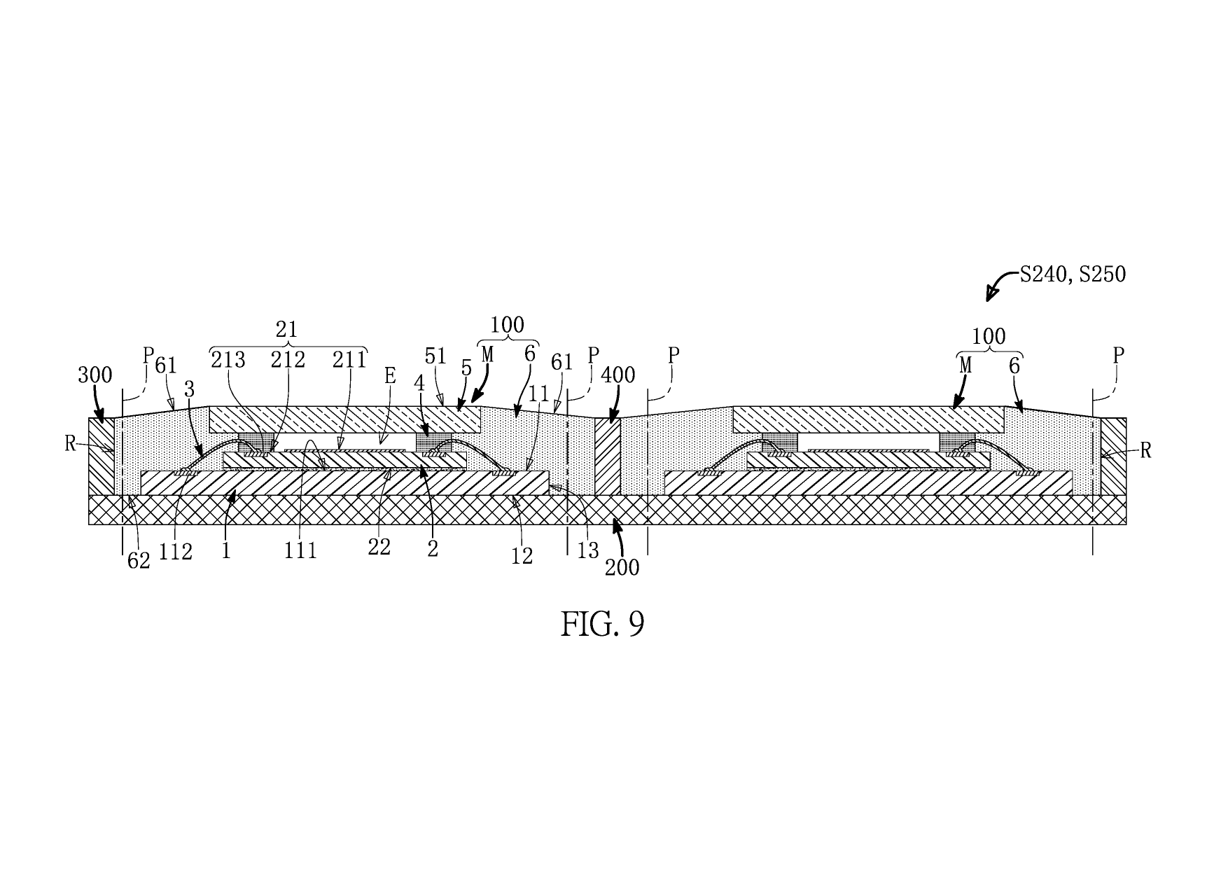

Referring to FIG. 7 to FIG. 9, a second embodiment of the present disclosure, which is similar to the first embodiment of the present disclosure, is provided. For the sake of brevity, descriptions of the same components in the first and second embodiments of the present disclosure will be omitted herein, and the following description only discloses different features between the first and second embodiments.

In the first dispensing step S230 of the present embodiment, a separation wall 400 is formed inside of the blocking wall 300 on the workbench 200 and is connected to the blocking wall 300 to jointly define a plurality of separation slots R, and each of the sensing modules M is arranged in one of the separation slots R. Moreover, in the second dispensing step S240, the encapsulant layer includes the encapsulants 6 that are respectively filled in the separation slots R and that are not in contact with each other. The slicing step S250 is implemented by cutting the encapsulant layer along a path P that is defined along an outer side of the sensing modules M and that is not in contact with the sensing modules M, so as to divide the encapsulant layer into the encapsulants 6 respectively covering the sensing modules M therein. Each of the sensing modules M and a corresponding one of the encapsulants 6 are jointly defined as one of a plurality of sensor package structures 100.

Specifically, in the first dispensing step S230, each of the sensing modules M is spaced apart from inner sides of the corresponding separation slot R by a same distance. Accordingly, in any one of the sensor package structures 100, two top side regions 61 of the encapsulant 6 respectively arranged at two opposite sides of the light-permeable sheet 5 are in a symmetrical arrangement with respect to the light-permeable sheet 5.

### Third Embodiment

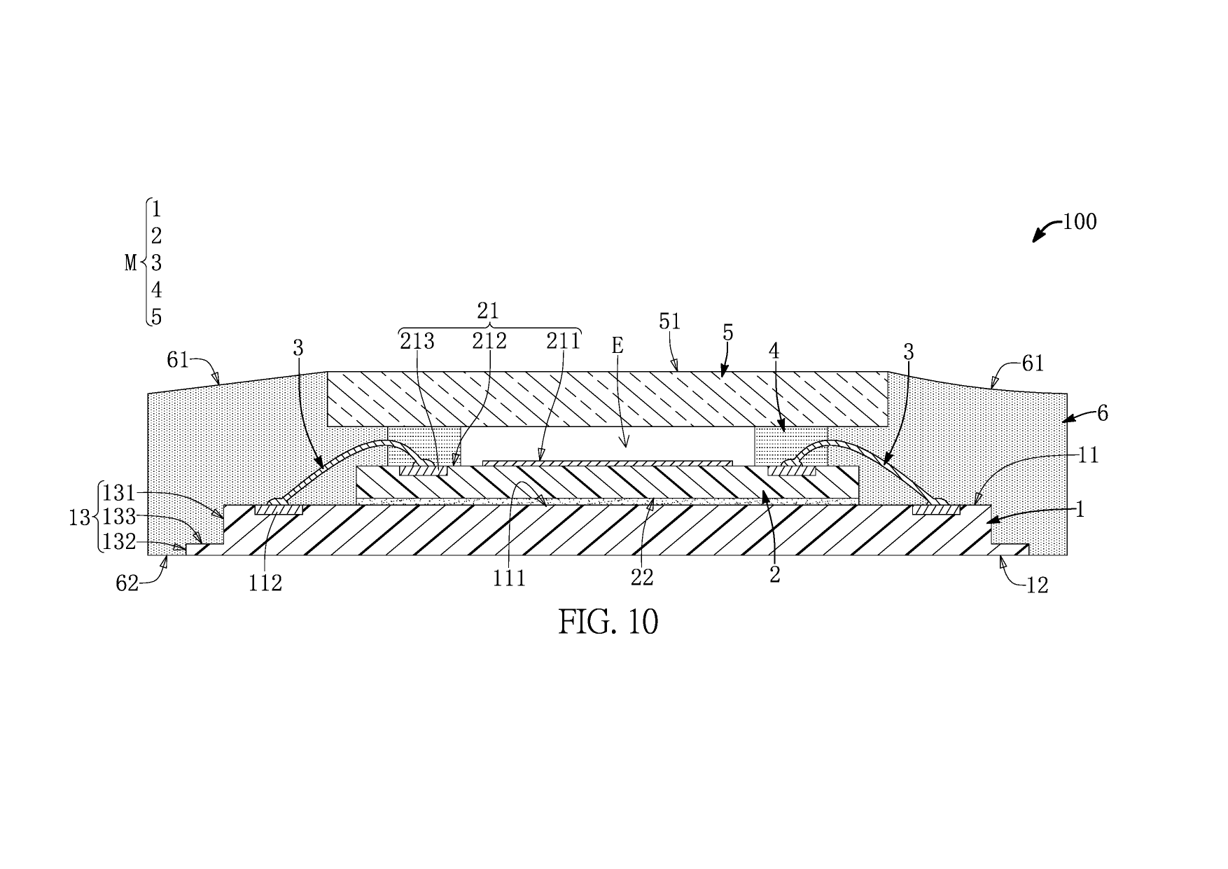

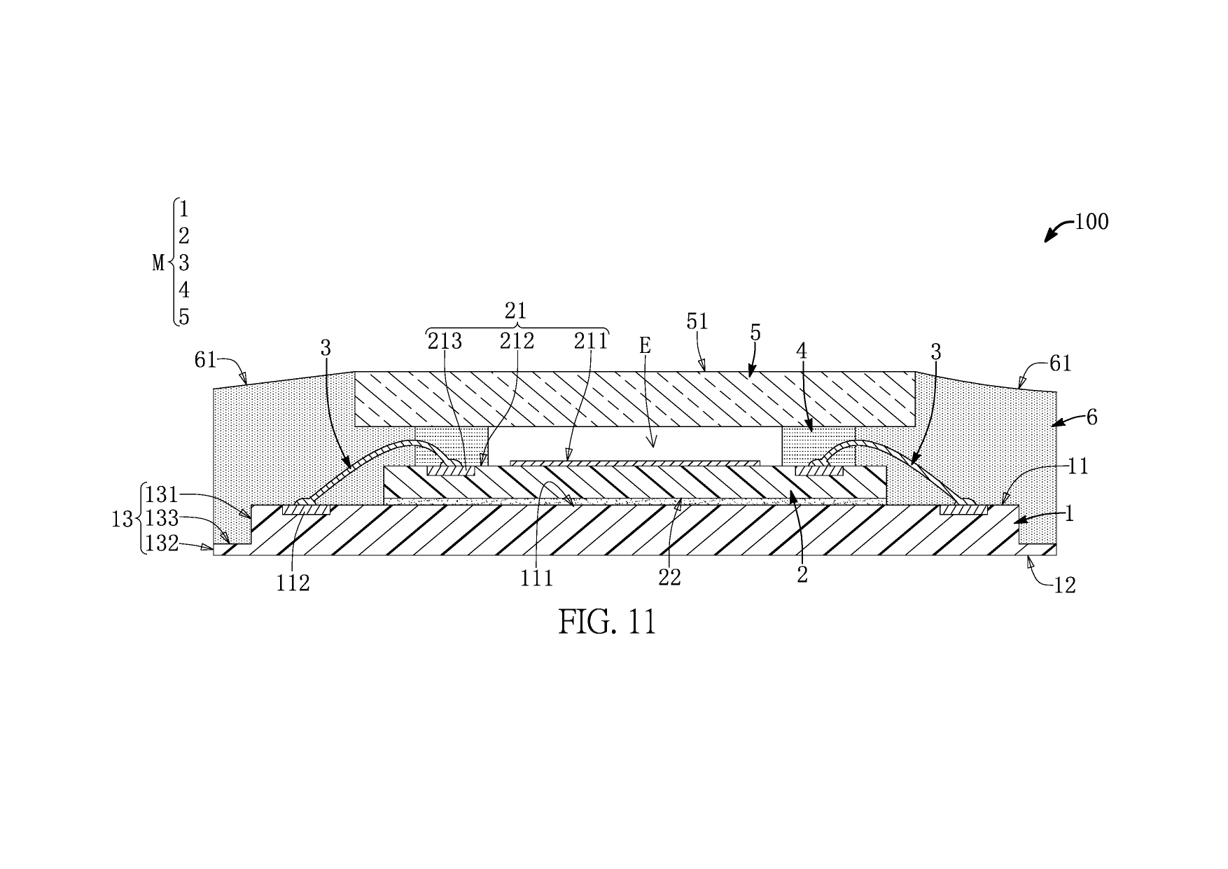

Referring to FIG. 10 and FIG. 11, a third embodiment of the present disclosure, which is similar to the first embodiment of the present disclosure, is provided. For the sake of brevity, descriptions of the same components in the first and third embodiments of the present disclosure will be omitted herein, and the following description only discloses different features between the first and third embodiments.

In the present embodiment, the surrounding lateral surface 13 of the ceramic substrate 1 has a ladder-like shape. In other words, the surrounding lateral surface 13 of the ceramic substrate 1 has a first riser surface 131 that is (perpendicularly) connected to the first surface 11, a second riser surface 132 that is (perpendicularly) connected to the second surface 12, and a tread surface 133 that is (perpendicularly) connected in-between the first riser surface 131 and the second riser surface 132. Each of the first riser surface 131, the second riser surface 132, and the tread surface 133 is in a ring shape. Moreover, as shown in FIG. 10, the first riser surface 131, the second riser surface 132, and the tread surface 133 can be embedded in the encapsulant 6. In addition, as shown in FIG. 11, the first riser surface 131 and the tread surface 133 are embedded in the encapsulant 6, and the second riser surface 132 is exposed from the encapsulant 6 and is flush with (or coplanar with) lateral sides of the encapsulant 6.

### Beneficial Effects of the Embodiments

In conclusion, in the sensor package structure and the manufacturing method thereof provided by the present disclosure, the encapsulant is provided to cover other components therein (e.g., all components of the sensing module being embedded in the encapsulant), so that the sensor package structure can have a good protective effect through the encapsulant (e.g., the surrounding lateral surface of the ceramic substrate being entirely protected by the encapsulant).

Moreover, a carrier of the sensor package structure provided by the present disclosure is chosen by the ceramic substrate having a small coefficient of thermal expansion (CTE), so that the ceramic substrate is not easily affected by the thermal expansion of the encapsulant to generate a warpage, thereby enabling the ceramic substrate to be embedded in the encapsulant. In other words, any package structure that does not have a ceramic substrate embedded in an encapsulant thereof is different from the sensor package structure of the present disclosure.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A manufacturing method of a sensor package structure, comprising:
a preparation step implemented by providing a plurality of sensing modules, wherein a manufacturing process of each of the sensing modules includes:
mounting and electrically coupling a sensor chip to a ceramic substrate;
forming a ring-shaped supporting layer on a top surface of the sensor chip; and
fixing a light-permeable sheet onto the ring-shaped supporting layer so as to form one of the sensing modules;
a placing step implemented by placing the ceramic substrates of the sensing modules on a workbench;
a first dispensing step implemented by forming a blocking wall on the workbench, wherein the blocking wall surrounds the sensing modules;
a second dispensing step implemented by forming an encapsulant layer inside of the blocking wall on the workbench, wherein the sensing modules are embedded in the encapsulant layer, and an outer surface of the light-permeable sheet of each of the sensing modules is at least partially exposed from the encapsulant layer; and
a slicing step implemented by cutting the encapsulant layer along a path that is defined along an outer side of the sensing modules and that is not in contact with the sensing modules, so as to divide the encapsulant layer into a plurality of encapsulants respectively covering the sensing modules therein, wherein each of the sensing modules and a corresponding one of the encapsulants are jointly defined as one of a plurality of sensor package structures.

2. The manufacturing method according to claim 1, wherein, in any one of the sensor package structures, two top side regions of the encapsulant respectively arranged at two opposite sides of the light-permeable sheet are in a non-symmetrical arrangement with respect to the light-permeable sheet.

3. The manufacturing method according to claim 1, wherein, in the first dispensing step, a separation wall is formed inside of the blocking wall on the workbench and is connected to the blocking wall to jointly define a plurality of separation slots, and each of the sensing modules is arranged in one of the separation slots, and wherein, in the second dispensing step, the encapsulant layer includes the encapsulants respectively filled in the separation slots.

4. The manufacturing method according to claim 3, wherein, in any one of the sensor package structures, two top side regions of the encapsulant respectively arranged at two opposite sides of the light-permeable sheet are in a symmetrical arrangement with respect to the light-permeable sheet.

5. The manufacturing method according to claim 1, wherein the manufacturing process of each of the sensing modules includes:
using a plurality of metal wires to connect the ceramic substrate and the sensor chip after the sensor chip is mounted on the ceramic substrate, such that the ceramic substrate and the sensor chip are electrically coupled to each other through the metal wires.

6. A sensor package structure, comprising:
a ceramic substrate having a first surface, a second surface being opposite to the first surface, and a surrounding lateral surface that is connected in-between the first surface and the second surface;
a sensor chip mounted on the first surface of the ceramic substrate and electrically coupled to the ceramic substrate, wherein a top surface of the sensor chip has a sensing region and a carrying region that surrounds the sensing region;
a ring-shaped supporting layer formed on the carrying region of the sensor chip;
a light-permeable sheet disposed on the ring-shaped supporting layer,
wherein the light-permeable sheet, the ring-shaped supporting layer, and the top surface of the sensor chip jointly define an enclosed space, and wherein the sensing region is located in the enclosed space; and
an encapsulant being formed on the first surface of the ceramic substrate and covering an entirety of the surrounding lateral surface, such that the ceramic substrate, the sensor chip, the ring-shaped supporting layer, and the light-permeable layer are embedded in the encapsulant;
wherein the second surface of the ceramic substrate and at least part of an outer surface of the light-permeable sheet are exposed from the encapsulant, and a bottom side of the encapsulant is flush with the second surface of the ceramic substrate.

7. The sensor package structure according to claim 6, wherein the surrounding lateral surface of the ceramic substrate has a first riser surface connected to the first surface, a second riser surface connected to the second surface, and a tread surface that is connected in-between the first riser surface and the second riser surface, and wherein the first riser surface, the second riser surface, and the tread surface are embedded in the encapsulant.

8. The sensor package structure according to claim 7, wherein each of the first riser surface, the second riser surface, and the tread surface is in a ring shape, and the tread surface is perpendicularly connected to the first riser surface and the second riser surface.

9. The sensor package structure according to claim 6, further comprising a plurality of metal wires connected to the ceramic substrate and the second chip, wherein the ceramic substrate and the second chip are electrically coupled to each other through the metal wires, and each of the metal wires is at least partially embedded in the encapsulant.

10. The sensor package structure according to claim 9, wherein the ceramic substrate includes a plurality of bonding pads arranged on the first surface, and the sensor chip is located inside of the bonding pads, wherein the top surface of the sensor chip includes a plurality of connection pads that are arranged on the carrying region and that are embedded in the encapsulant, and wherein one end of the metal wires is connected to the bonding pads, and another end of the metal wires is connected to the connection pads and is embedded in the ring-shaped supporting layer.

11. A sensor package structure, comprising:
a ceramic substrate having a first surface, a second surface being opposite to the first surface, and a surrounding lateral surface that is connected in-between the first surface and the second surface, wherein the surrounding lateral surface of the ceramic substrate has a first riser surface connected to the first surface, a second riser surface connected to the second surface, and a tread surface that is connected in-between the first riser surface and the second riser surface;
a sensor chip mounted on the first surface of the ceramic substrate and electrically coupled to the ceramic substrate, wherein a top surface of the sensor chip has a sensing region and a carrying region that surrounds the sensing region;
a ring-shaped supporting layer formed on the carrying region of the sensor chip;
a light-permeable sheet disposed on the ring-shaped supporting layer, wherein the light-permeable sheet, the ring-shaped supporting layer, and the top surface of the sensor chip jointly define an enclosed space, and wherein the sensing region is located in the enclosed space; and
an encapsulant being formed on the first surface of the ceramic substrate and covering the first riser surface and the tread surface, such that the sensor chip, the ring-shaped supporting layer, and the light-permeable layer are embedded in the encapsulant;
wherein the second surface of the ceramic substrate and at least part of an outer surface of the light-permeable sheet are exposed from the encapsulant.
